(19) United States
(12) Patent Application Publication
(10) Pub. No.: US 2015/0214416 A1
(43) Pub. Date: Jul. 30, 2015

(54) METHOD OF PACKAGE FOR SENSOR CHIP

(71) Applicant: STACK DEVICES CORP., Miaoli (TW)

(72) Inventors: Mon-Nan HO, Miaoli (TW); Chien-Heng LIN, Miaoli (TW); Ching-Shui CHENG, Miaoli (TW); Po-Wen CHOU, Miaoli (TW)

(73) Assignee: STACK DEVICES CORP., Miaoli (TW)

(21) Appl. No.: 14/166,668

(22) Filed: Jan. 28, 2014

(51) Int. Cl. H01L 31/18; H01L 31/0232; H01L 31/02; H01L 31/0203

(52) U.S. Cl. CPC H01L 31/18; H01L 31/0203; H01L 31/02325; H01L 31/02002

(57) ABSTRACT

A method of package for sensor chip includes the steps of: a) providing a sensor chip having a plurality of conducting contacts and a sensing area, b) using an adhesive to bond the sensor chip on a circuit substrate, c) mounting a dam between the sensing area and conducting contacts of the sensor chip, d) connecting metal conducting wires between the conducting contacts of the circuit substrate and the conducting contacts of the sensor chip, and e) molding a molding compound on the circuit substrate and the sensor chip to cover the metal conducting wires and the dam. Thus, the dam can buffer the impact of stress on the sensor chip during the step e). Further, an open type sensing space is defined after the step e), facilitating signal or status sensing and improving the sensor chip package yield rate.

### BACKGROUND OF THE INVENTION

1. Field of the Invention

The present invention relates to semiconductor chip packaging technology, and more particularly to a method of package for sensor chip that effectively protects the packaged sensor chip.

2. Description of the Related Art

Referring to FIG. 1, a conventional sensor chip packaging method is known for packing a CCD (charge coupled device) or CMOS (complementary metal-oxide-semiconductor) sensor chip 10. This methods includes the step of allocating the sensor chip 10 on a circuit substrate and then bonding metal wires 12 to electrically connect the conducting contacts of the sensor chip 10 and the respective conducting contacts of the circuit substrate 11, and then the step of applying an adhesive 16 to the sensor chip 10 between the conducting contacts thereof, and then the step of placing a glass plate 14 on the adhesive above a sensing area 15 of the sensor chip 10, and then molding a special packaging material on the circuit substrate 11, the sensor chip 10 and the glass plate 14 to form a package 13. Thus, the metal conductive wires 12 are fixedly embedded in the package 13 and will not break easily, and the sensing area 15 of the sensor chip 10 is well protected by the glass plate 14 for sensing a signal or status outside the glass plate 14.

However, according to the above-mentioned sensor chip packaging method, the short distance between the sensing area 15 of the sensor chip 10 and the glass plate 14 subject to the thickness of the adhesive 16 can affect the signal or status sensing of the sensor chip 10. Therefore, the above-mentioned sensor chip packaging method has a low yield rate and needs to be improved.

Referring to FIG. 2, an improved sensor chip packaging method was then created to improve the above-mentioned sensor chip packaging method. This improved method includes the step of placing the sensor chip 10 on the circuit substrate 11 and then bonding the metal conducting wires 12 to electrically connect the conducting contacts of the sensor chip 10 and the respective conducting contacts of the circuit substrate 11, and then the step of placing a frame member 17 having a through hole downwardly extended from the top wall thereof onto the circuit substrate 11 to shield the metal conducting wires 12, and then the step of bonding a glass plate 14 to the top wall of the frame member 17 over the through hole of the frame member 17 and right above the sensing area 15 of the sensor chip 10 so that a sensing space 18 is defined between the glass plate 14 and the sensing area 15. Thus, the sensing area 15 of the sensor chip 10 is well protected by the glass plate 14 and can sense an induced signal or status outside the glass plate 14.

However, according to the aforesaid improved sensor chip packaging method, there is no any auxiliary fixation means to hold down the metal conducting wires 12, the metal conducting wires have an increased risk of fracture during the packaging process, lowering the sensor chip production yields. An improvement in this regard is necessary.

### SUMMARY OF THE INVENTION

The present invention has been accomplished under the circumstances in view. It is the main object of the present invention to provide a method of package for sensor chip, which improves sensor chip production yield and product performance.

To achieve this and other objects of the present invention, a method of package for sensor chip in accordance with the present invention includes the steps of:

a) providing a sensor chip having a plurality of conducting contacts and a sensing area; b) using an adhesive to bond the sensor chip on a circuit substrate that has a plurality of conducting contacts for electrically connection with the conducting contacts of the sensor chip; c) mounting a dam on the sensor chip between the sensing area and conducting contacts of the sensor chip; d) connecting metal conducting wires between the conducting contacts of the circuit substrate and the conducting contacts of the sensor chip; and e) molding a molding compound on the circuit substrate and the sensor chip to cover the metal conducting wires and the dam.

During steps c) through the step e), the dam can buffer the impact of stress on the sensor chip, avoiding the sensor chip damage. Further, an open type sensing space is defined after the step e), facilitating signal or status sensing and improving the sensor chip package yield rate.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is a sectional view illustrating a sensor chip package structure packaged subject to a conventional packaging method.

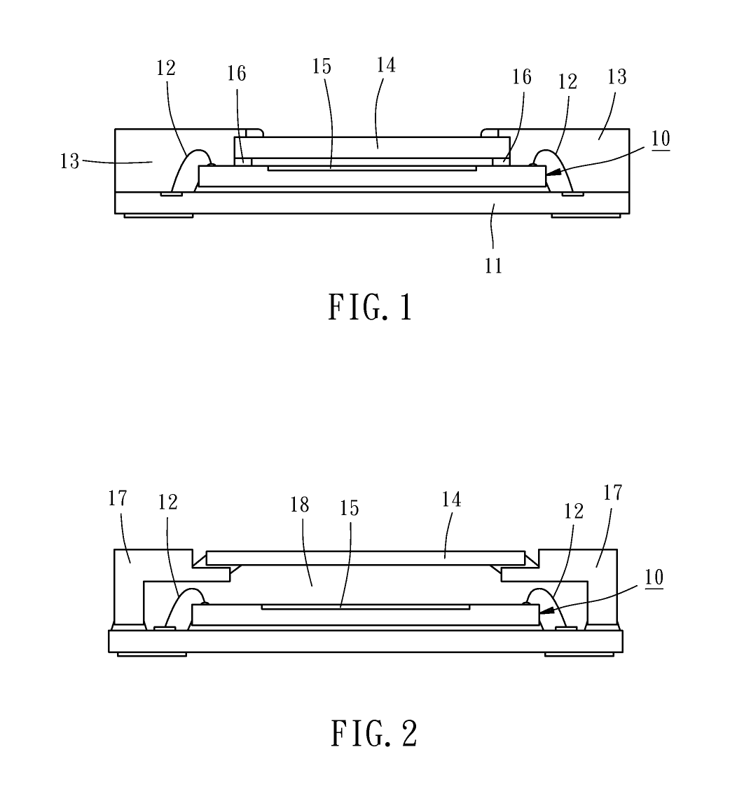

FIG. 2 is a sectional view illustrating a sensor chip package structure packaged subject to another conventional packaging method.

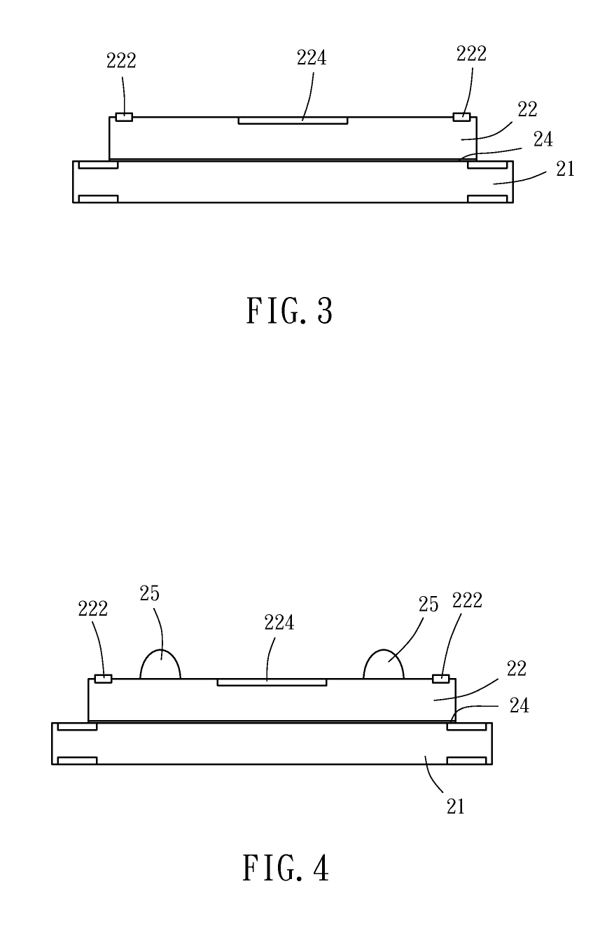

FIGS. 3-6 are schematic sectional structural views illustrating the performance of a method of package for sensor chip in accordance with a first embodiment of the present invention.

FIGS. 7-9 are schematic sectional structural views illustrating the performance of a method of package for sensor chip in accordance with a second embodiment of the present invention.

FIG. 10 is schematic sectional structural view illustrating a sensor chip package structure packaged in accordance with a third embodiment of the present invention.

### DETAILED DESCRIPTION OF THE INVENTION

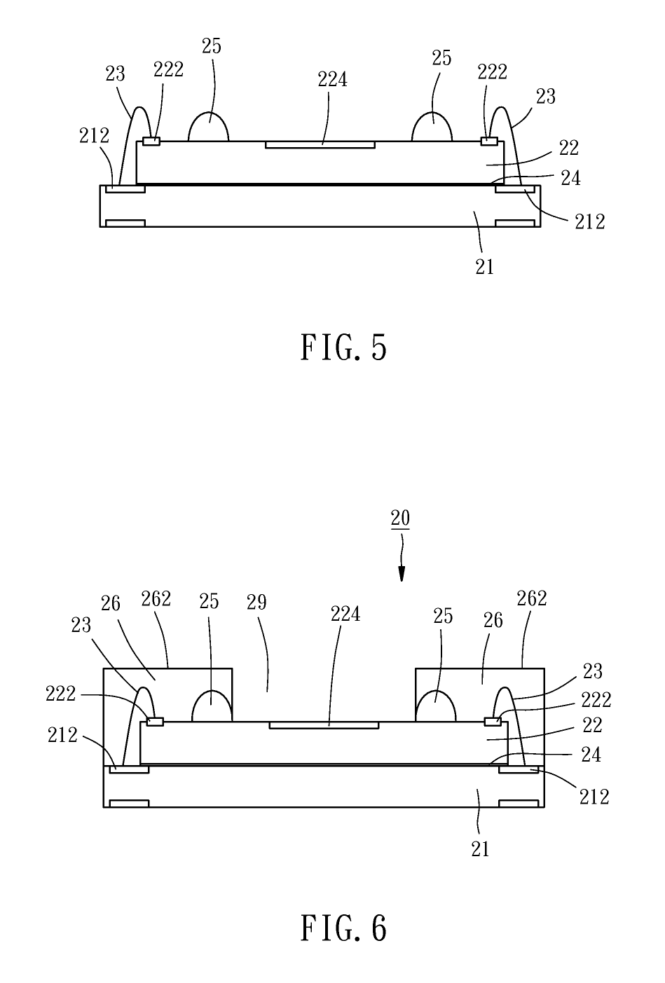

Referring to FIGS. 3-6, a package structure 20 packaged in accordance with a first embodiment of the present invention is shown. The method of packaging this package structure 20 (see FIG. 6) is outlined hereinafter.

The method of package for sensor chip in accordance with the first embodiment of the present invention comprises the steps of:

a) as shown in FIG. 3, providing a sensor chip 22 having a plurality of conducting contacts 222 and a sensing area 224;

b) as shown in FIG. 3, using an adhesive 24 to bond the sensor chip 22 on a circuit substrate 21 that has a plurality of conducting contacts 212 for connecting with the conducting contacts 222 of the sensor chip 22;

c) as shown in FIG. 4, mounting a dam 25 between the sensing area 224 and conducting contacts 222 of the sensor chip 22;

d) as shown in FIG. 5, connecting metal conducting wires 23 between the conducting contacts 212 of the circuit substrate 21 and the conducting contacts 222 of the sensor chip 22; and

e) as shown in FIG. 6, molding a molding compound 26 on the circuit substrate 21 and the sensor chip 22 to cover the metal conducting wires 23 and the dam 25 without covering the sensing area 224 of the sensor chip 22.

Further, the number and size of the dam are unrestricted, and can be determined subject to actual requirements. Further, it is practical to perform step c) prior to step b), and then proceed to step d) and then step e) without affecting the formation of the package structure 20.

Further, the number of the metal conducting wires 23 in step d) is unrestricted, and can be determined subject to actual requirements. Further, step d) is the known art. Further, it is practical to perform step d) prior to step c), and then proceed to step c) and then step e) without affecting the formation of the package structure 20.

Thus, the arrangement of the dam 25 and the molding compound 26 effectively can buffer the impact of stress on the sensor chip 22 during the step e). Further, an open type sensing space 29 is defined after the step e). Further, the dam 25 can be mounted on the sensor chip 22 between the sensing area 224 and conducting contacts 222 of the sensor chip 22 using a conventional coating technique, or a screen printing technique. Alternatively, the dam 25 can be made using a mold casting process, and then mounted on the sensor chip 22 between the sensing area 224 and conducting contacts 222 of the sensor chip 22. Further, the molding compound 26 is formed of a special packaging material with a molding technique to cover and regulate the metal conducting wire 23 and the dam 25, protecting the metal conducting wire 23 and the dam 25 against breaking damage and improving the sensor chip package yield rate.

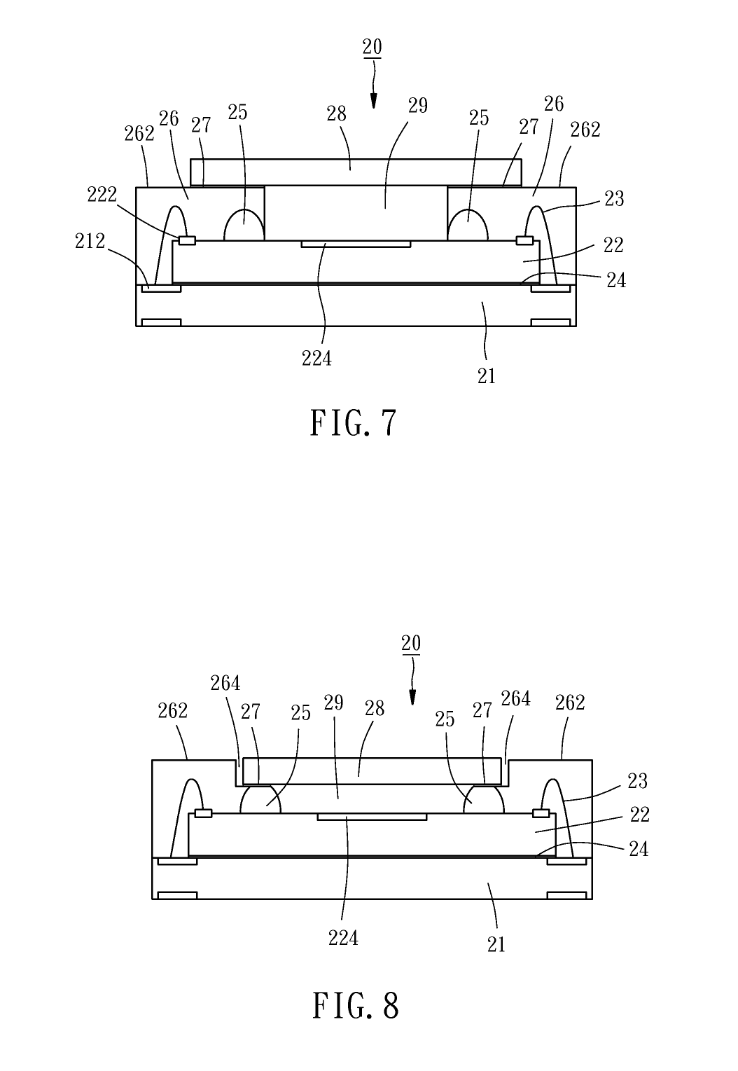

Referring to FIGS. 7-9, a sensor chip package structure in accordance with a second embodiment of the present invention is shown. According to this second embodiment, a cover member 28 (see FIG. 7) that admits light is mounted on a top wall 262 of the molding compound 26 right above the sensing area 224 of the sensor chip 22 such that a sensing space 29 is defined between the cover member 28 and the sensor chip 22 and surrounded by the molding compound 26.

Further, in this embodiment, the cover member 28 is a glass member with excellent light permeability, and bonded on the top wall 262 of the molding compound 26 with an adhesive 27. Thus, the sensing area 224 of the sensor chip 22 is well protected by the cover member 28, and capable of sensing an induced signal or status outside the cover member 28.

Referring to FIG. 8 again, the top wall 262 of the molding compound 26 has a recess 264 inwardly recessed in direction toward the sensing area 224 of the sensor chip 22. Further, the cover member 28 is bonded to the recess 264 with the adhesive 27. Referring to FIG. 9 again, in this embodiment, the cover member 28 has a through hole 282 disposed in vertical alignment with the sensing area 224 of the sensor chip 22. Thus, this embodiment effectively reduces the overall height of the package structure 20, achieving a low profile design. Through the through hole 282 of the cover member 28, the signal or status sensing performance of the sensing area 224 of the sensor chip 22 is enhanced. Thus, a sensor chip package of this design is suitable for use in a low profile electronic product, such as camera, cell phone, notebook computer, temperature sensor, humidity sensor, pressure sensor, blood glucose sensor, ECG sensor or radar sensor.

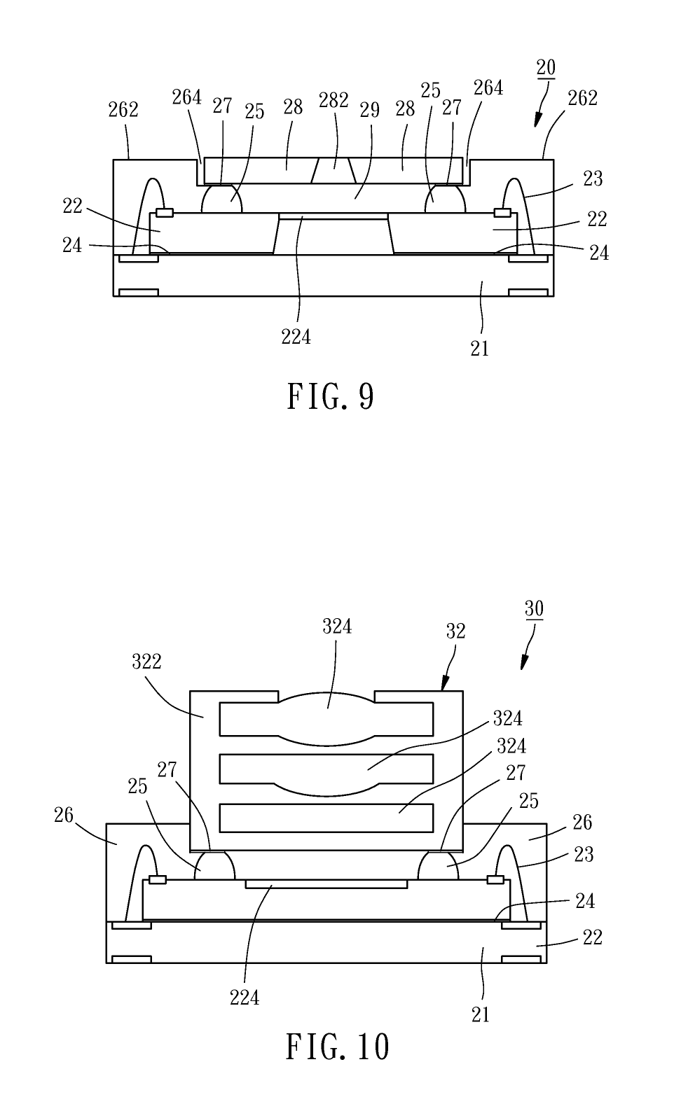

Referring to FIG. 10, a sensor chip package structure 30 in accordance with a third embodiment of the present invention is shown. This sensor chip package structure 30 is substantially similar to the above-described sensor chip package structure 20 with the exception that the cover member 32 of the sensor chip package structure 30 is a camera lens that is of the known art, comprising a lens barrel 322 and a plurality of optical lenses 324. In the method of package for this sensor chip package structure 30, the lens barrel 322 of the cover member 32 is mounted in the recess 264 of the molding compound 26. Further, the height of the molding compound 26 is smaller than or equal to the height of the cover member 32. Thus, the sensor chip package structure 30 can be directly mounted in a camera, cell phone, notebook computer or any other electronic product, enabling the electronic product to have a sensor chip and a camera lens, without further camera lens installation. Thus, this embodiment facilitates camera lens installation.

In the above-described various embodiments of method of package for sensor chip of the present invention, the cover member is not restricted to a glass material or camera lens. Any cover member made of any other material in any other form that is capable of enabling the sensing area 224 of the sensor chip 22 to sense an induced signal or status outside the cover member can be adopted.

Although particular embodiments of the present invention have been described in detail for purposes of illustration, various modifications and enhancements may be made without departing from the spirit and scope of the invention. Accordingly, the invention is not to be limited except as by the appended claims.

What is claimed is:

1. A method of package for sensor chip, comprising the steps of:
a) providing a sensor chip (22) having a plurality of conducting contacts (222) and a sensing area (224);
b) using an adhesive (24) to bond said sensor chip (22) on a circuit substrate (21) that has a plurality of conducting contacts (212);
c) mounting a dam (25) on said sensor chip (22) between the sensing area (224) and conducting contacts (222) of said sensor chip (22);
d) connecting metal conducting wires (23) between the conducting contacts (212) of said circuit substrate (21) and the conducting contacts (222) of said sensor chip (22); and
e) molding a molding compound (26) on said circuit substrate (21) and said sensor chip (22) to cover said metal conducting wires (23) and said dam (25).

2. The method of package for sensor chip as claimed in claim 1, further comprising a sub step of mounting a cover member (28) on a top wall (262) of said molding compound (26) right above said sensing area (224) of said sensor chip (22), enabling a sensing space (29) to be defined between said cover member (28) and said sensing area (224).

3. The method of package for sensor chip as claimed in claim 2, wherein said cover member (28) admits light.

4. The method of package for sensor chip as claimed in claim 1, further comprising a sub step of mounting a cover member (28) in a recess (264) in a top wall (262) of said molding compound (26) right above said sensing area (224) of said sensor chip (22).

5. The method of package for sensor chip as claimed in claim 4, wherein said cover member (28) admits light.

6. The method of package for sensor chip as claimed in claim 1, further comprising a sub step of mounting a cover member (28) on said molding compound (26) right above said sensing area (224) of said sensor chip (22), said cover member (28) having at least one through hole (282) vertically aimed at said sensing area (224) of said sensor chip (22).

7. The method of package for sensor chip as claimed in claim 1, wherein in said step c), said dam (25) on said sensor chip (22) between the sensing area (224) and conducting contacts (222) of said sensor chip (22) using a screen printing technique.

8. The method of package for sensor chip as claimed in claim 1, wherein in said step c), said dam (25) is made using a mold casting process and then mounted on said sensor chip (22) between the sensing area (224) and conducting contacts (222) of said sensor chip (22).

9. The method of package for sensor chip as claimed in claim 1, wherein said step d) is performed prior to said step c) and after said step a), and said step c) and said step e) are then preceded in a proper order.

10. The method of package for sensor chip as claimed in claim 9, further comprising a sub step of mounting a cover member (28) on a top wall (262) of said molding compound (26) right above said sensing area (224) of said sensor chip (22), enabling a sensing space (29) to be defined between said cover member (28) and said sensing area (224).

11. The method of package for sensor chip as claimed in claim 10, wherein said cover member (28) admits light.

12. The method of package for sensor chip as claimed in claim 9, further comprising a sub step of mounting a cover member (28) in a recess (264) in a top wall (262) of said molding compound (26) right above said sensing area (224) of said sensor chip (22).

13. The method of package for sensor chip as claimed in claim 12, wherein said cover member (28) admits light.

14. The method of package for sensor chip as claimed in claim 9, further comprising a sub step of mounting a cover member (28) on said molding compound (26) right above said sensing area (224) of said sensor chip (22), said cover member (28) having at least one through hole (282) vertically aimed at said sensing area (224) of said sensor chip (22).

15. The method of package for sensor chip as claimed in claim 1, wherein said step c) is performed prior to said step b) and after said step a), and said step d) and said step e) are then preceded in a proper order after said step b).

16. The method of package for sensor chip as claimed in claim 15, further comprising a sub step of mounting a cover member (28) on a top wall (262) of said molding compound (26) right above said sensing area (224) of said sensor chip (22), enabling a sensing space (29) to be defined between said cover member (28) and said sensing area (224).

17. The method of package for sensor chip as claimed in claim 16, wherein said cover member (28) admits light.

18. The method of package for sensor chip as claimed in claim 15, further comprising a sub step of mounting a cover member (28) in a recess (264) in a top wall (262) of said molding compound (26) right above said sensing area (224) of said sensor chip (22).

19. The method of package for sensor chip as claimed in claim 18, wherein said cover member (28) admits light.

20. The method of package for sensor chip as claimed in claim 15, further comprising a sub step of mounting a cover member (28) on said molding compound (26) right above said sensing area (224) of said sensor chip (22), said cover member (28) having at least one through hole (282) vertically aimed at said sensing area (224) of said sensor chip (22).
